(19) United States
(12) Patent Application Publication
(10) Pub. No.: US 2010/0012988 A1
(43) Pub. Date: Jan. 21, 2010

(54) METAL OXIDE SEMICONDUCTOR DEVICES HAVING IMPLANTED CARBON DIFFUSION RETARDATION LAYERS AND METHODS FOR FABRICATING THE SAME

(75) Inventors: Frank Bin YANG, Mahwah, NJ (US); Michael J. HARGROVE, Clinton Corners, NY (US); Rohit PAL, Fishkill, NY (US)

Correspondence Address: INGRASSIA FISHER & LORENZ, P.C. (AMD), 7010 E. COCHISE ROAD, SCOTTSDALE, AZ, 85253, US

(73) Assignee: Advanced Micro Devices, Inc., Austin, TX (US)

(21) Appl. No.: 12/176,916

(22) Filed: Jul. 21, 2008

(51) Int. Cl. H01L 29/00; H01L 21/8236

(52) U.S. Cl. 257/288; 438/278; 257/E21.631; 257/E29.001

(57) ABSTRACT

Semiconductor devices and methods for fabricating semiconductor devices are provided. One exemplary method comprises providing a silicon-comprising substrate having a first surface, etching a recess into the first surface, the recess having a side surface and a bottom surface, implanting carbon ions into the side surface and the bottom surface, and forming an impurity-doped, silicon-comprising region overlying the side surface and the bottom surface.

### FIELD OF THE INVENTION

The present invention generally relates to semiconductor devices and methods for fabricating semiconductor devices, and more particularly relates to metal oxide semiconductor devices having implanted carbon diffusion-retardation layers and methods for fabricating such semiconductor devices.

### BACKGROUND OF THE INVENTION

As the pitch between individual devices on integrated circuits (ICs) continues to shrink with each new technology generation, components of these devices including gate electrodes and spacers are scaled down in size accordingly. Spacers used as masks for source and drain implantation processes provide a self-alignment of the source and drain (S/D) to the gate electrode and shadow the channel region from impinging dopant ions. Spacers thereby play a critical role in creating desirable dopant profiles in the source and drain and keep the S/D dopant from the channel to prevent S/D punch through. However, reducing the thickness of spacers decreases the separation between the channel and doped source/drain regions, thereby increasing the risk that dopants may diffuse into the channel during subsequent processing. In particular, post-implant annealing processes that subject devices to a considerable thermal budget of time and temperature may cause dopant species to diffuse relatively long distances from implanted regions. Advanced devices having narrowed spacers characteristic of the 45 nm technology node and beyond are especially susceptible to this condition as even low concentrations of either P-type S/D dopants (for PMOS devices) or N-type S/D dopants (for NMOS devices) in the channel can lead to undesirable short channel effects (SCE) and a degradation in device performance.

The threat of source/drain punch through caused by excessive dopant diffusion into the channel can be mitigated somewhat by reducing the thermal budget of post-implant annealing processes to decrease the range of diffusing species. However, such reductions are limited by the need to achieve the beneficial aspects of annealing including recovery of implantation-induced defects, more complete activation of the dopant, and a low external resistance (Rₑₓₜ). Unfortunately, processing advanced devices with even a minimized thermal budget can potentially introduce enough dopant atoms into the channel to adversely affect its short channel control. Co-implanting small concentrations of a diffusion inhibiting species with the primary III or V dopant material can provide the advantage of decreasing the diffusion coefficient of such dopants. For example, the diffusion rates of boron (B) and phosphorous (P) in silicon during annealing processes are significantly reduced when the boron and phosphorous have been co-implanted with a low concentration of carbon (C) atoms. However, co-implanting carbon with boron or phosphorous introduces challenges. For example, when relatively fast-diffusing dopant atoms such as B or P migrate beyond a carbon-containing, co-implanted region during an annealing process, they resume a normal, rapid diffusion rate and may still migrate into the channel.

Accordingly, it is desirable to provide semiconductor devices having implanted carbon diffusion-retardation layers interposed between the channel and the source and drain regions. Further, it is desirable to provide methods for fabricating such semiconductor devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method is provided for fabricating source and drain regions for a semiconductor device in accordance with one exemplary embodiment of the invention. The method comprises providing a silicon-comprising substrate having a first surface, etching a recess into the first surface, the recess having a side surface and a bottom surface, implanting carbon ions into the side surface and the bottom surface, and forming an impurity-doped, silicon-comprising region overlying the side surface and the bottom surface.

In accordance with a further exemplary embodiment of the invention, a method of fabricating an MOS transistor on a silicon-comprising substrate having a first surface is provided. The method comprises forming a gate stack comprising a gate electrode having sidewalls disposed on the first surface of the silicon-comprising substrate, forming offset spacers adjacent to the sidewalls of the gate electrode, etching the first surface of the silicon-comprising substrate using the gate stack and the offset spacers as an etch mask to form recesses in the silicon-comprising substrate, the recesses exposing second surfaces of the silicon-comprising substrate, implanting carbon ions into the second surfaces of the silicon-comprising substrate using the gate stack and the offset spacers as an ion implantation mask, and epitaxially forming impurity-doped, silicon-comprising regions in the recesses.

An MOS transistor is provided in accordance with yet another exemplary embodiment of the invention. The MOS transistor comprises a silicon substrate having a surface, an epitaxially-grown, impurity-doped region disposed at the surface of the silicon substrate, and a carbon-comprising region interposed between the surface of the silicon substrate and the epitaxially-grown, impurity-doped region.

### BRIEF DESCRIPTION OF THE DRAWINGS

The present invention will hereinafter be described in conjunction with the following drawing figures, wherein like numerals denote like elements, and wherein:

FIGS. 1-8 illustrate an MOS transistor and methods for fabricating MOS transistors in accordance with exemplary embodiments of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention result in the fabrication of an MOS transistor having a carbon-comprising, diffusion-retardation layer disposed underlying the deep source and drain regions to reduce the diffusion rate of source/drain impurity dopants such as phosphorous, arsenic, or boron. The diffusion retardation layer significantly reduces the diffusion coefficient of dopants within the layer and thereby reduces the range of dopant diffusion during high temperature annealing processes and, accordingly, the risk of dopant diffusion into the channel region of a MOS device. Further, because the rate of diffusion of dopants is reduced, a wider processing window to use conventional post-implant annealing processes is available with fewer associated harmful effects from diffusion.

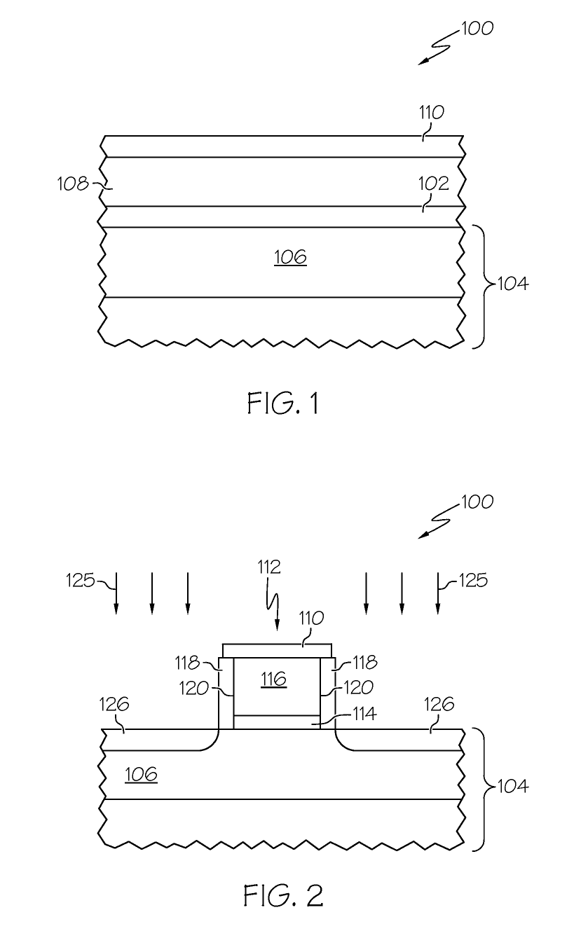

FIGS. 1-8 illustrate schematically, in cross section, methods for forming an MOS transistor 100 in accordance with exemplary embodiments of the invention. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a silicon-comprising substrate. The embodiments herein described refer to an N-channel MOS (NMOS) or a P-channel MOS (PMOS) transistor. While the fabrication of only one MOS transistor is illustrated, it will be appreciated that the method depicted in FIGS. 1-8 can be used to fabricate any number of such transistors. Various steps in the manufacture of MOS components are well known and so, in the interest of brevity, many conventional steps will only be mentioned briefly herein or will be omitted entirely without providing the well known process details.

Referring to FIG. 1, the method begins by forming a gate insulator material 102 overlying a silicon substrate 104. The term “silicon substrate” is used herein to encompass the relatively pure silicon materials typically used in the semiconductor industry as well as silicon admixed with other elements such as germanium, carbon, and the like. The silicon substrate may be a bulk silicon wafer, or may be a thin layer of silicon on an insulating layer (commonly know as silicon-on-insulator or SOI) that, in turn, is supported by a carrier wafer. At least a surface 106 of the silicon substrate is impurity doped, for example by forming N-type well regions and P-type well regions for the fabrication of P-channel (PMOS) transistors and N-channel (NMOS) transistors, respectively.

Typically, the gate insulating material 102 can be a layer of thermally grown silicon dioxide or, alternatively (as illustrated), a deposited insulator such as a silicon oxide, silicon nitride, or the like. Deposited insulators can be deposited, for example, by chemical vapor deposition (CVD), low pressure chemical vapor deposition (LPCVD), or plasma enhanced chemical vapor deposition (PECVD). Gate insulator layer 102 preferably has a thickness of about 1-10 nm, although the actual thickness can be determined based on the application of the transistor in the circuit being implemented.

A layer of gate electrode material 108 is formed overlying the gate insulating material 102. In accordance with one embodiment of the invention, the gate electrode material is polycrystalline silicon. The layer of polycrystalline silicon is preferably deposited as undoped polycrystalline silicon and is subsequently impurity doped by ion implantation. The polycrystalline silicon can be deposited by LPCVD by the hydrogen reduction of silane. A layer of hard mask material 110, such as silicon nitride or silicon oxynitride, can be deposited onto the surface of the polycrystalline silicon. The hard mask layer 110 can be deposited to a thickness of about 50 nm, also by LPCVD.

Referring to FIG. 2, the hard mask layer 110 is photolithographically patterned and the underlying gate electrode material layer 108 and the gate insulating material layer 102 are anisotropically etched to form a gate stack 112 having a gate insulator 114 and a gate electrode 116. The polycrystalline silicon can be etched in the desired pattern by, for example, reactive ion etching (RIE) using a Cl⁻ or HBr/O₂ chemistry and the hard mask and gate insulating material can be etched, for example, by RIE in a CHF₃, CF₄, or SF₆ chemistry. In one exemplary embodiment, reoxidation sidewall spacers 118 are formed about sidewalls 120 of gate electrode 116 by subjecting the gate electrode 116 to high temperature in an oxidizing ambient. The reoxidation sidewall spacers 118 have a thickness of, for example, about 3 to 4 nm.

Source and drain extensions 126 are next formed by appropriately impurity doping substrate 104 in a known manner, for example, by ion implantation of dopant ions (illustrated by arrows 125), and subsequent annealing. By using the gate stack 112 as an implantation mask, the source and drain extensions 126 are self-aligned thereto. For an N-channel MOS transistor the source and drain extensions 126 are preferably formed by implanting phosphorus ions, although arsenic ions may also be used. For a P-channel MOS transistor, the source and drain extensions 126 are preferably formed by implanting boron ions. MOS transistor 100 then may be cleaned to remove any oxide that has formed on the silicon substrate surface 106 using, for example, dilute hydrofluoric acid.

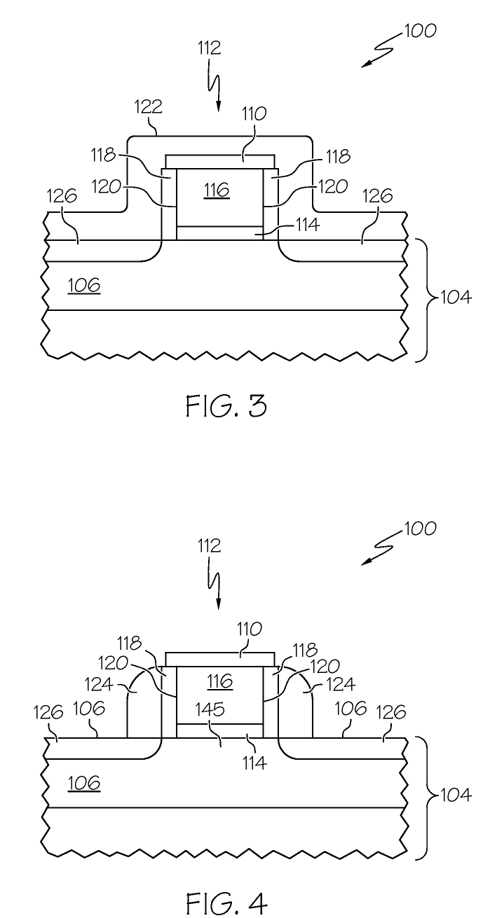

After the formation of the source and drain extensions 126, a blanket layer 122 of dielectric material is deposited overlying MOS structure 100, as illustrated in FIG. 3. The dielectric material 122 layer may comprise, for example, silicon dioxide and is anisotropically etched, as described above, to form second spacers 124, often referred to as offset spacers, adjacent to the reoxidation sidewall spacers 118, as illustrated in FIG. 4. The offset spacers 124 have a thickness of, for example, about 10 to about 20 nm. While FIG. 4 illustrates MOS transistor 100 with only one set of offset spacers 124, it will be understood that the invention is not so limited and MOS transistor 100 may have more than one set of offset spacers as is suitable for a desired functionality of MOS transistor 100.

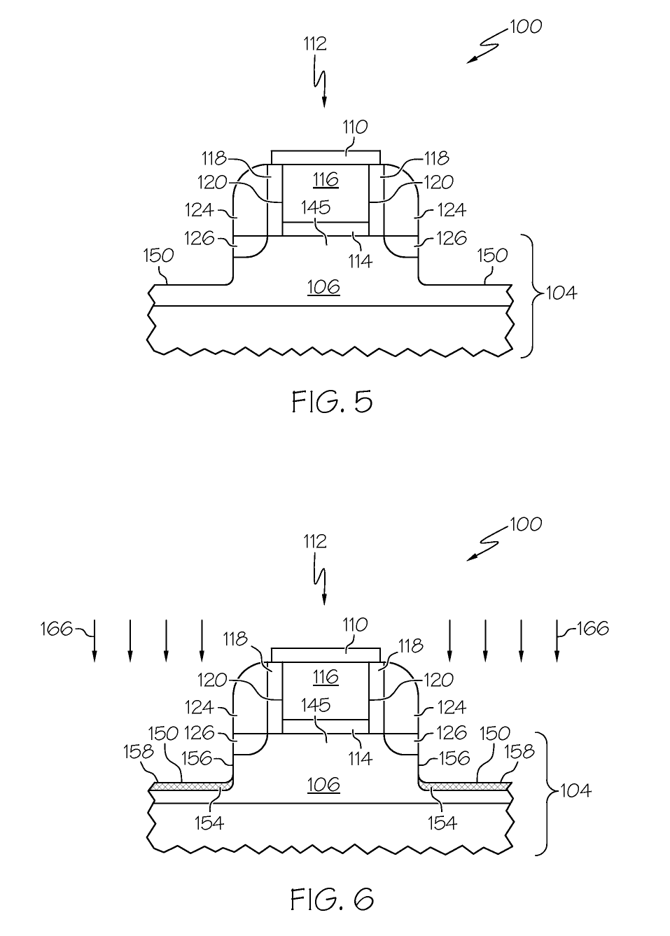

Referring to FIG. 5, recesses 150 are anisotropically etched into the silicon substrate 104 adjacent to the gate stack 112 using the gate stack 112 and offset spacers 124 as an etch mask. The recesses can be etched by, for example, reactive ion etching (RIE) using an HBr/O₂ chemistry. According to one exemplary embodiment, the recesses 150 are etched to a depth of about from 50 nm to 100 nm and preferably to about 60 nm.

Referring to FIG. 6, in one exemplary embodiment, a first ion implantation process is performed to implant carbon ions (represented by arrows 166) into the bottom surfaces 158 of recesses 150. The accelerating voltage used to implant carbon ions can be adjusted to achieve the depth of penetration desired. Further, the dose current also may be varied to control the desired ion concentration. During this process, the bottom surfaces 158 of the recesses 150 and/or the axis of a source ion beam are oriented relative to each other so that the bottom surfaces 158 are substantially orthogonal to the source ion beam axis, which results in the formation of a carbon-implanted layer 154 predominantly in the bottom surfaces 158. The recesses 150, formed by the previous anisotropic etch process, feature substantially vertical side surfaces 156 that remain substantially shielded from implantation by offset spacers 124. In one embodiment, the first implantation process uses an acceleration voltage of about from 1 keV to 15 keV and a dose of about from 1.0×10¹³ to 1.0×10¹⁵ cm⁻². In accordance with this embodiment, the thickness of carbon-implanted layer 154 is in a range of about from 1 nm to about 20 nm, or is preferably about 15 nm thick.

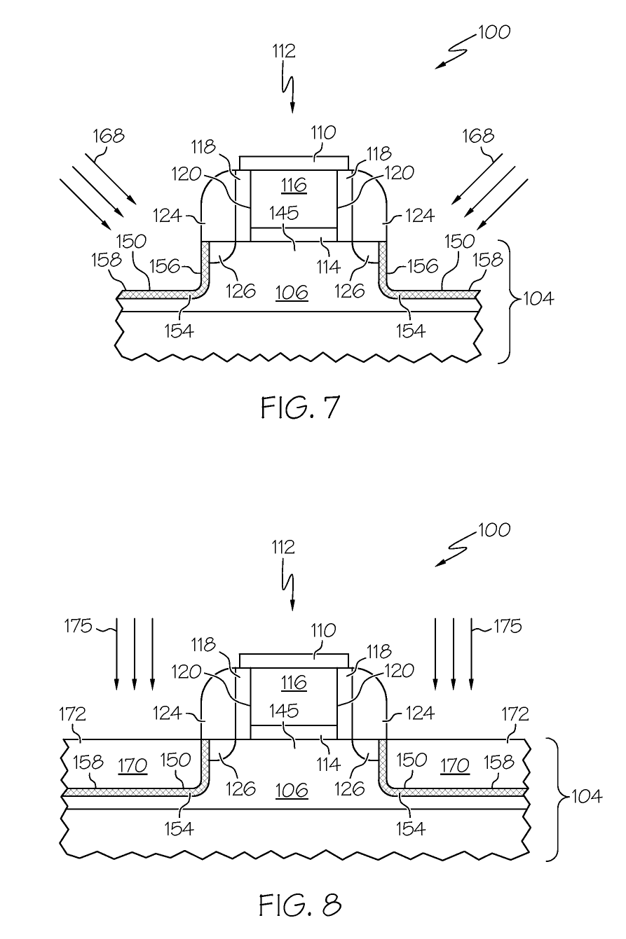

Referring to FIG. 7, a second ion implantation process is performed to implant carbon ions (represented by arrows 168) into the side surfaces 156 of recesses 150. In one exemplary embodiment, carbon atoms are implanted into side surfaces 156 of recesses 150 by orienting the axis of the source ion beam and/or the bottom surfaces 158 of substrate 104 so that the bottom surfaces 158 are at an angle to the source ion beam that is greater than zero degrees and less than 90 degrees. In one exemplary embodiment, the angle, relative to the bottom surfaces 158, is in a range of from about 5 degrees to about 30 degrees to remove the shadowing effect on side surfaces 156 from offset spacers 124. The second implantation process uses an acceleration voltage of about from 1 to 15 keV and a dose of about from 1×10¹³ to 1×10¹⁵ cm⁻² and preferably a voltage of about from 5 to 10 keV and a dose of about from 2×10¹⁴ cm⁻² to 4×10¹⁴ cm⁻². This second implantation process is tailored to augment the first carbon ion implantation process and extend carbon-implanted layer 154 to provide a carbon-implanted layer 154 at the bottom and side surfaces 158 and 156 respectively, exposed by the etch of recess 150. By implanting the carbon atoms at an angle relative to the bottom surfaces 158, offset spacers 124 provide a shadowing effect to the bottom surfaces 158 of recesses 150, and substantially deter further carbon implantation thereon. In accordance with one embodiment, the thickness of layer 154 is in a range of about from 10 nm to about 30 nm, or preferably is about 20 nm. The final concentration of implanted carbon in layer 154 is in a range of about from 5×10¹⁸ atoms/cm⁻³ to 2×10¹⁹ atoms/cm⁻³ and preferably about 1×10¹⁹ atoms/cm⁻³. It should be understood that while the order of implantation processing has been described such that bottom surfaces 158 are implanted before side surfaces 156, this order may be reversed.

Referring to FIG. 8, following the first and second carbon implantation processes, a silicon-comprising film 170 is epitaxially grown on silicon substrate 104 in recesses 150 to form the deep source and drain regions 172 of transistor 100. The epitaxial process is performed selectively to silicon surfaces so that growth on non-silicon surfaces such as offset spacers 124 or hardmask layer 110 is prevented. The presence of hardmask layer 110 overlying the polysilicon gate electrode 116 thereby prevents epitaxial growth on gate electrode 116 that might otherwise occur. The epitaxial silicon-comprising film 170 can be grown by the reduction of silane (SiH₄) or dichlorosilane (SiH₂Cl₂) in the presence of hydrochloric acid (HCl) to control growth selectivity. In one exemplary embodiment of the invention, in addition to the epitaxial-growth reactants, impurity-doping elements are provided to appropriately dope the deep source and drain regions 172 as the silicon-comprising film 170 is epitaxially grown. For example, boron can be added to the reactants during the epitaxial growth of deep source/drain regions for PMOS applications and arsenic or phosphorous can be added to the reactants during the epitaxial growth of deep source/drain regions for NMOS applications. In another embodiment, referring to FIG. 8, the deep source and drain regions 172 can be impurity doped after the epitaxial growth of silicon-comprising film 170 by an ion implantation process using the offset spacers 124 as an implantation mask. For example, boron ions (represented by arrows 175) may be implanted to form the deep source and drain regions 172 of PMOS devices while phosphorous or arsenic ions may be implanted to form these regions for NMOS devices. For MOS devices that feature both PMOS and NMOS type transistors, an appropriate photolithographic masking step may be performed to protect the source/drain regions of one type while the other type is being implanted.

In an alternative embodiment, the silicon-comprising film 170 may be epitaxially grown in the presence of additional stress-inducing elements such as, for example, carbon or germanium, to incorporate them thereby into the crystalline lattice. In one exemplary embodiment, the epitaxial material chosen for a PMOS transistor is preferably silicon germanium (SiGe) used to apply a compressive stress to a channel 145 and increase the mobility of majority carrier holes therein. In a further embodiment, the SiGe can include up to about 40% germanium, and preferably contains about from 25 to 35% germanium.

In a further exemplary embodiment, deep source and drain regions 172 for NMOS transistors may be fabricated in a similar manner by epitaxially growing a monocrystalline material such as silicon carbon (SiC) used to apply a tensile stress to channel 145 and increase the mobility of majority carrier electrons therein. In yet a further embodiment, the epitaxial SiC film 170 can include up to about 3% carbon and preferably includes about 2% carbon. In yet a further embodiment applicable to NMOS devices wherein a reverse-SiGe structure is used (SiGe epitaxially grown in a region beneath channel 145), the deep source and drain regions 172 may be formed by epitaxially growing a monocrystalline, impurity-doped silicon film.

MOS transistor 100 is next subjected to an annealing process such as by, for example, rapid thermal annealing (RTA). The anneal allows damage to the lattice caused by preceding implantation processes to be repaired and allows impurity dopants to become activated by migrating to lattice sites, providing lower overall device Rₑₓₜ thereby. In one exemplary embodiment, MOS transistor 100 is annealed for about 1 millisecond to about 10 seconds at a temperature of about from 950° C. to 1100° C., or preferably at about 1050° C. for about 1 second. In a further embodiment, other annealing techniques may be used including laser annealing.

Accordingly, the deep source and drain regions 172 of MOS transistor 100 are bounded within the substrate 104 by a carbon-comprising diffusion retardation layer 154. This retardation layer reduces the diffusion rate of dopant atoms such as boron or phosphorous migrating from deep source/drain regions 172, thus slowing the diffusion of the dopant atoms toward channel 145 during subsequent high-temperature annealing processes. The retardation layer 154 allows a greater thermal budget to be applied to the device during fabrication to achieve the advantageous effects thereof. These include more complete recovery of implantation-induced defects, greater activation of the dopant, and a reduced external resistance. Further, the procedures described herein can be readily integrated into a more comprehensive process used to fabricate MOS devices.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

What is claimed is:

1. A method for fabricating source and drain regions for a semiconductor device, the method comprising the steps of:
providing a silicon-comprising substrate having a first surface;
etching a recess into the first surface, the recess having a side surface and a bottom surface;
implanting carbon ions into the side surface and the bottom surface; and
forming an impurity-doped, silicon-comprising region overlying the side surface and the bottom surface.

2. The method of claim 1, wherein the step of forming comprises forming an ion implanted, impurity-doped, silicon-comprising region.

3. The method of claim 1, wherein the step of forming comprises epitaxially growing an in situ doped, silicon-comprising region.

4. The method of claim 1, wherein the step of implanting carbon ions comprises the step of implanting carbon ions wherein the bottom surface and a source ion beam axis are oriented relative to each other so that the bottom surface is substantially orthogonal to the source ion beam axis.

5. The method of claim 1, wherein the step of implanting carbon ions comprises the step of implanting carbon ions wherein the bottom surface and a source ion beam axis are oriented relative to each other so that an angle therebetween is greater than zero degrees and less than 90 degrees.

6. The method of claim 1, further comprising the step of forming a gate stack and offset spacers overlying the silicon-comprising substrate and wherein the step of implanting carbon ions comprises the step of implanting carbon ions using the gate stack and the offset spacers as implant masks.

7. The method of claim 1, wherein the step of implanting carbon ions comprises the step of implanting carbon ions using an accelerating voltage in the range of about from 1 keV to 15 keV and a dose range of about from 1×10¹³ to 1×10¹⁵ cm⁻².

8. The method of claim 7, wherein the step of implanting carbon ions comprises the step of implanting carbon ions using an accelerating voltage of about 5 keV and a dose of about 2×10¹⁴ cm⁻².

9. The method of claim 1, wherein the step of implanting carbon ions comprises the step of implanting carbon ions to form a carbon-comprising layer at the side surface and the bottom surface, the carbon-comprising layer having a thickness in the range of about from 10 nm to 30 nm.

10. The method of claim 1, wherein the step of forming an impurity-doped, silicon-comprising region comprises epitaxially growing a silicon-comprising region further comprising carbon or germanium.

11. The method of claim 1, wherein the step of etching a recess into the first surface comprises etching a recess into the first surface that is in a range of about from 50 nm to 100 nm in depth.

12. A method of fabricating an MOS transistor on a silicon-comprising substrate having a first surface, the method comprising the steps of:
forming a gate stack comprising a gate electrode having sidewalls, the gate stack disposed on the first surface of the silicon-comprising substrate;
forming offset spacers adjacent the sidewalls of the gate electrode;
etching the first surface of the silicon-comprising substrate using the gate stack and the offset spacers as an etch mask to form recesses in the silicon-comprising substrate, the recesses exposing second surfaces of the silicon-comprising substrate;
implanting carbon ions into the second surfaces of the silicon-comprising substrate using the gate stack and the offset spacers as an ion implantation mask; and
epitaxially forming impurity-doped, silicon-comprising regions in the recesses.

13. The method of claim 12, further comprising the step of annealing the substrate using rapid thermal annealing.

14. The method of claim 12, further comprising the step of annealing the substrate at a temperature of about from 950° C. to 1100° C. and for a time of from about 5 milliseconds to about 5 seconds.

15. The method of claim 12, wherein the step of epitaxially forming impurity-doped, silicon-comprising regions comprises forming impurity-doped, silicon-comprising regions that further comprise carbon or germanium.

16. The method of claim 12, wherein the step of implanting carbon ions comprises the step of implanting carbon ions using an accelerating voltage in the range of about from 1 keV to 15 keV and a dose range of about from 1×10¹³ to 1×10¹⁵ cm⁻².

17. The method of claim 16, wherein the step of implanting carbon ions comprises the step of implanting carbon ions using an accelerating voltage of about 5 keV and a dose of about 2×10¹⁴ cm⁻².

18. The method of claim 12, wherein the step of implanting carbon ions comprises the step of implanting carbon ions to form a carbon-comprising layer having a thickness in the range of about from 10 nm to 30 nm.

19. The method of claim 18, wherein the step of implanting carbon ions comprises the step of implanting carbon ions to form a carbon-comprising layer having a thickness of about 20 nm.

20. An MOS transistor comprising:
a silicon substrate having a surface;
an epitaxially-grown, impurity-doped region disposed at the surface of the silicon substrate; and
a carbon-comprising region interposed between the surface of the silicon substrate and the epitaxially-grown, impurity-doped region.
